(19) United States
(12) Patent Application Publication
(10) Pub. No.: US 2013/0198695 A1
(43) Pub. Date: Aug. 1, 2013

(54) Multi-Gate Field Effect Transistor with A Tapered Gate Profile

(71) Applicant: International Business Machines Corporation, Armonk, NY (US)

(72) Inventors: Andres Bryant, Burlington, VT (US); Josephine B. Chang, Mahopac, NY (US); Wilfried Haensch, Somers, NY (US); Effendi Leobandung, Wappingers Falls, NY (US); Chung-Hsun Lin, White Plains, NY (US)

(73) Assignee: INTERNATIONAL BUSINESS MACHINES CORPORATION, Armonk, NY (US)

(21) Appl. No.: 13/644,398

(22) Filed: Oct. 4, 2012

Related U.S. Application Data
(63) Continuation of application No. 13/363,651, filed on Feb. 1, 2012.

(51) Int. Cl. G06F 17/50

(52) U.S. Cl. 716/50

(57) ABSTRACT

A multi-gate field effect transistor apparatus and method for making same. The apparatus includes a source terminal, a drain terminal, and a gate terminal which includes a tapered-gate profile. A method for designing a multi-gate field effect transistor includes arranging a source terminal, a drain terminal and a gate terminal with a tapered-gate profile to create a wider gate width on a bottom of a fin.

### CROSS-REFERENCE TO RELATED APPLICATIONS

This application is a continuation of U.S. patent application Ser. No. 13/363,651, filed Feb. 1, 2012, incorporated by reference herein.

### FIELD OF THE INVENTION

Embodiments of the invention generally relate to electronic devices and, more particularly, to electronic circuitry.

### BACKGROUND

With respect to multi-gate field effect transistors (MG FETs), the physical location of the minimum potential barrier, or the path for maximum drain leakage current, is located at the center bottom of the fin where the electrostatic control from the gate is the weakest. The extra electrostatic control from vertical ends—that is, the top gate or bottom gate—reduces the short channel effect. The threshold voltage (Vth) roll-off decreases as fin height (H_{fin}) decreases.

As used herein, Vth roll-off is defined as the drop of Vth from long channel to short channel devices in a Vth versus Lgate plot. The potential barrier at this most leaky path decreases as fin height increases, resulting in an H_{fin} dependence of short channel effects.

Accordingly, there is a need to improve the short channel behavior of the bottom fin in multi-gate field effect transistors.

### SUMMARY

In one aspect of the invention, a multi-gate field effect transistor (FET) with a tapered gate is provided. The multi-gate field effect transistor includes a source terminal, a drain terminal, and a gate terminal which includes a tapered-gate profile.

Another aspect of the invention includes a method for designing a multi-gate field effect transistor. The method includes arranging a source terminal, a drain terminal and a gate terminal with a tapered-gate profile to create a wider gate width on a bottom of a fin.

These and other objects, features and advantages of the present invention will become apparent from the following detailed description of illustrative embodiments thereof, which is to be read in connection with the accompanying drawings.

### BRIEF DESCRIPTION OF THE DRAWINGS

FIG. 1 is a diagram illustrating a three-dimensional view of a multi-gate field effect transistor with a vertical gate profile;

FIG. 2 is a diagram illustrating a two-dimensional view of a multi-gate field effect transistor with a vertical gate profile;

FIG. 3 is a diagram illustrating a two-dimensional view of a multi-gate field effect transistor with a reversed tapered-gate profile;

FIG. 4 is a diagram illustrating a two-dimensional view of a multi-gate field effect transistor with a tapered-gate profile, according to an embodiment of the present invention; and

FIG. 5 is a graph illustrating performance of multiple gate profiles, according to an embodiment of the present invention.

### DETAILED DESCRIPTION

An aspect of the invention includes a multi-gate field effect transistor (FET) with a tapered gate profile. The tapered gate profile creates a longer gate length in the bottom of the fin, thereby improving the short channel behavior of the bottom fin. Additionally, as detailed herein, the tapered gate profile also improves transistor performance for a given off-state current.

Due to the three-dimensional (3D) nature of such structures, the current flowing in through the bottom portion of the fin gets the weakest gate control compared to other current. Accordingly to an embodiment of the invention, one approach to reduce the penalty of less gate control is to increase the gate electrode length (gate length). Therefore, by making a gate tapered in FinFET (that is, a nonplanar, multi-gate transistor built on a substrate), a structure in accordance with at an embodiment of the instant invention will provide the benefit of longer gate length in the bottom portion of the fin that lessens short channel effect penalty.

As such, and as further detailed herein, embodiments of the invention can be implemented in FinFETs that are constructed via general, known process and with general, known materials and parameters as per used (and as would be appreciated) by one skilled in the art.

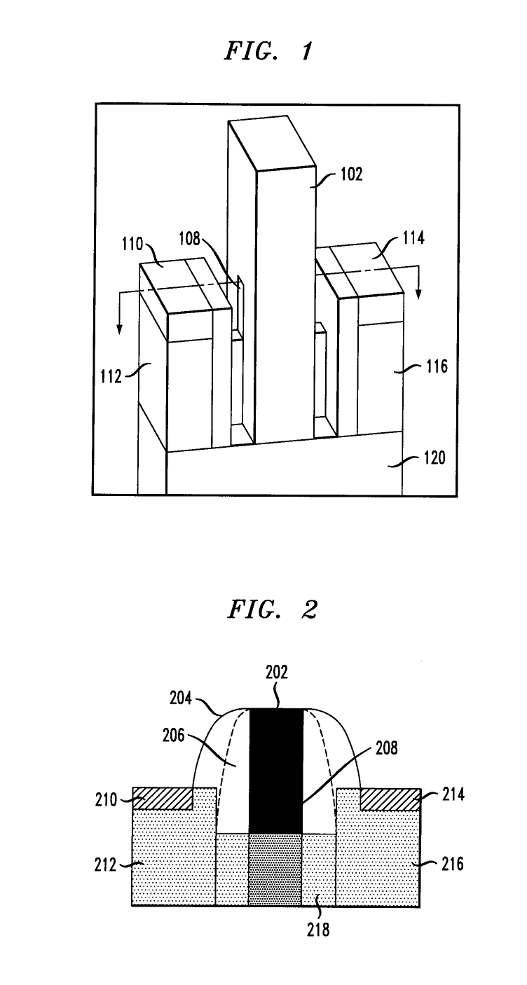

FIG. 1 is a diagram illustrating a three-dimensional view of a multi-gate field effect transistor with a vertical gate profile. By way of illustration, FIG. 1 depicts gate electrode 102 (with a vertical gate profile), hardmask 108, silicide 110, epi source/drain 112, silicide 114, epi source/drain (S/D) 116 and oxide insulator 120. The gate electrode 102 is the electrode to connect the gate terminal to an external contact, a link or other nodes. An embodiment of the invention can include a spacer, which is an isolation layer between the gate electrode and the S/D contact to prevent the gate to S/D short hardmask. Such as illustrated in FIG. 1, a spacer can include a nitride or oxide layer 120 to provide the protection of a certain portion of material during an etch process. Silicide (components 110 and 114) is a Si/metal alloy layer that is used between the metal and Si interface to reduce contact resistance.

Additionally, in connection with the example embodiment detailed in FIG. 1, the epi source/drain (components 112 and 116) is the epitaxially grown material in the S/D area to merge the multiple fins together at the S/D region channel. An embodiment of the invention can include a S/D region channel, which is a region under the gate and between S/D, where the current flow path proceeds from source to drain.

In an aspect of the invention, the thickness of the hardmask (HM) can vary, including an embodiment of the invention where there is no hardmask present/included at all. Accordingly, by way of example, the thickness of the hardmask can range from the same thickness as the sidewall oxide (indicating, for example, no hardmask) which can include a range of approximately 0.5 nanometers (nm) to 3 nm. Note that this is merely an example and it is to be appreciated by one skilled in the art that such a range need not be limited.

In at least one other embodiment of the invention, the thickness of the hardmask can range from approximately 20-30 nm independent of sidewall oxide thickness (indicating, for example, that a hardmask is present/included). Note again that this is merely an example and it is to be appreciated by one skilled in the art that such a range need not be limited.

Additionally, as illustrated in FIG. 1, in at least one embodiment of the invention, the gate electrode 102 wraps around the hardmask 108 and the fin (source/drain component). Further, the silicide (components 110 and 114) is located on top of a merged source/drain (S/D).

FIG. 2 is a diagram illustrating a two-dimensional view of a multi-gate field effect transistor (FET) with a vertical gate profile. By way of illustration, FIG. 2 depicts gate electrode 202 (with a vertical gate profile), a spacer 204, a spacer 206, a hardmask 208, silicide 210, epi source/drain 212, silicide 214, epi source/drain 216 and channel 218. As the depiction of FIG. 2 is a two-dimensional view of the transistor apparatus, the portion of the gate electrode that cannot be seen in this view is superimposed over the channel 218 (lightly shaded), also referred to herein as the fin.

In contrast to an example embodiment of the invention (see, for example, FIG. 4), the vertical gate profile depicted in FIG. 2 is disadvantageous due to the reduced gate control in the bottom of fin and strong spreading resistance penalty for current flow in that region.

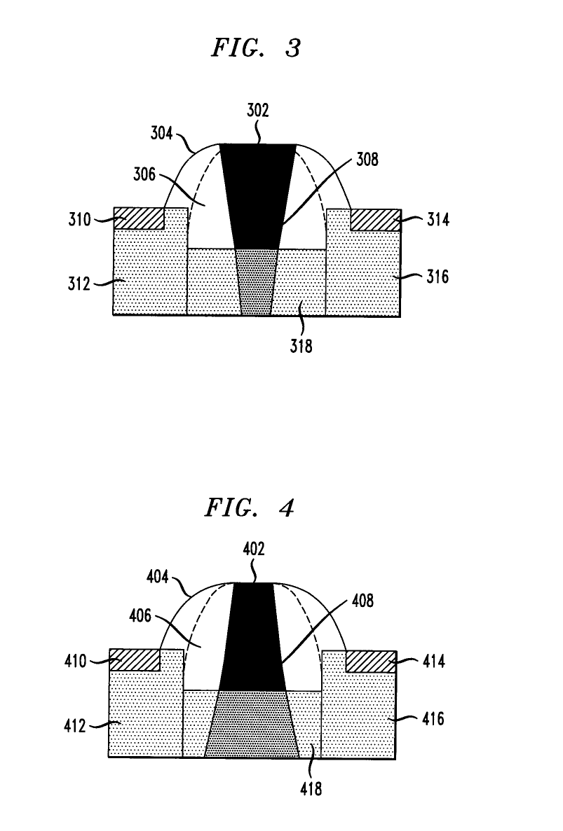

FIG. 3 is a diagram illustrating a two-dimensional view of a multi-gate field effect transistor with a reversed tapered-gate profile. By way of illustration, FIG. 3 depicts gate electrode 302 (with a reversed tapered-gate profile), spacer 304, spacer 306, hardmask 308, silicide 310, epi source/drain 312, silicide 314, epi source/drain 316 and channel 318. As the depiction of FIG. 3 is a two-dimensional view, the portion of the gate electrode that cannot be seen in this view is superimposed over the channel 318 (lightly shaded), also referred to herein as the fin.

In contrast to an example embodiment of the invention (see, for example, FIG. 4) and similar to the vertical gate profile of FIG. 2, the reverse tapered-gate profile depicted in FIG. 3 is disadvantageous due to the reduced gate control in the bottom of fin and strong spreading resistance penalty (even more penalty than the vertical gate profile of FIG. 2) for current flow in that region.

Additionally, FIG. 4 is a diagram illustrating a two-dimensional view of a multi-gate field effect transistor with a tapered-gate profile, according to an embodiment of the present invention. By way of illustration, FIG. 4 depicts a gate electrode 402 with a tapered-gate profile, a spacer 404, a spacer 406, a hardmask 408, silicide 410, epi source/drain 412, silicide 414, epi source/drain 416 and channel 418. As the depiction of FIG. 4 is a two-dimensional view, the portion of the gate electrode that cannot be seen in this view is superimposed over the channel 418 (lightly shaded), also referred to herein as the fin.

The components identified in FIG. 4, similar to those detailed in FIG. 1, are described as follows. The gate electrode 402 is the electrode to connect the gate terminal to an external contact, a link or other nodes. A spacer (component 404 or 406) is the isolation layer between the gate electrode and the S/D contact to prevent the gate to S/D short hardmask. For example, a spacer can include a nitride or oxide layer to provide the protection of a certain portion of material during an etch process. Silicide (components 410 and 414) is a Si/metal alloy layer that is used between the metal and Si interface to reduce contact resistance.

Additionally, the epi source/drain (component 412 or 416) is the epitaxially grown material in the S/D area to merge the multiple fins together at the S/D region channel. The S/D region channel 418 is a region under the gate and between S/D, where the current flow path proceeds from Source to Drain.

Unlike the disadvantage vertical and reverse tapered-gate profiles illustrated in FIGS. 2 and 3, the tapered-gate profile of the embodiment of the invention depicted in FIG. 4 provides improved short-channel effect (SCE) at the bottom of the fin due to a longer Lgate. Further, the tapered-gate profile of the embodiment of the invention depicted in FIG. 4 additionally provides lower spreading resistance penalty due to less current flow.

The tapered-gate profile contained within embodiments of the invention can be implemented via a range of angles with respect to the taper. According to an aspect of the invention, the angle of the tapered-gate can range from approximately zero degrees (that is, vertical) to 90 degrees.

In an example embodiment of the invention, the bottom portion of a tapered gate can have a width of five nanometers (nm) greater than the width of the top portion. In additional embodiments of the invention, the width of the bottom portion of the tapered gate can be determined by a user/designer of the Fin FET. By way of example, the width of the bottom portion of the tapered gate can include a range from approximately 0 nm to approximately 20 nm.

Also, in an embodiment of the invention, the doping profile is flush with the gate profile (that is, L_{eff}=L_{gate}). In other embodiments of the invention, a doping profile can overlap the tapered-gate profile. Additionally, in an embodiment of the invention, the tapered-gate profile can overlap a doping profile. Also, by way merely of example and not limitation, a BOX doping profile is an example profile that can be used and that indicates doping is constant in the entire cuboid.

Additionally, contact resistivity of a tapered-gate structure can include, by way of example, 1E-8 ohms per square centimeter (ohm-cm²). In additional embodiments of the invention, the contact resistivity of a tapered-gate structure can include a range from approximately 1E-7 to approximately 1E-10. Further, by way of example, in an embodiment of the invention, the hardmask can be an optional component.

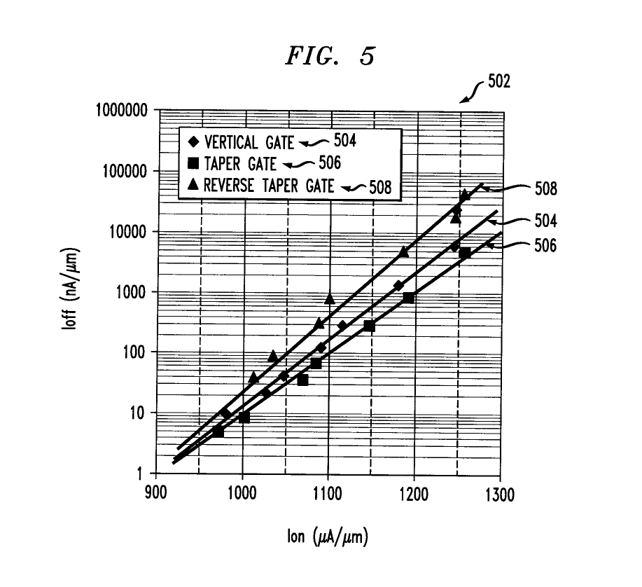

FIG. 5 is a graph 502 illustrating performance of multiple gate profiles, according to an embodiment of the present invention. By way of illustration, FIG. 5 depicts vertical gate data 504, tapered-gate data 506 and reverse tapered-gate data 508. As used herein, Ioff is the leakage current measured at gate bias=zero and drain bias=Vdd (power supply pin). Further, Ion is the current measured at gate=drain bias=Vdd. As illustrated in graph 502, the tapered-gate profile shows the best performance of the three sets of data.

Fully-silicided (FUSI) contact shows a deviation between tapered-gate and reverse-tapered-gate data. Accordingly, at least one embodiment of the invention includes a longer/wider bottom PC (that is, gate), which improves the SCE of the leakiest path (for example, the middle bottom of a fin).

Further, in an embodiment of the invention, a top portion of a channel of the field effect transistor apparatus has additional gate field control via the hardmask, and a bottom portion of a channel of the field effect transistor apparatus has additional drain field penetration via the doping profile. In embodiments of the invention that include a hardmask, the gate terminal wraps around the hardmask. Additionally, as detailed herein, the thickness of the hardmask can vary.

Additionally, as described herein, a multi-gate field effect transistor apparatus in accordance with an embodiment of the invention can include a tapered-gate profile that provides longer gate length in a bottom portion of a fin to lessen short channel effect penalty. Also, the tapered-gate profile can include an angle of the tapered-gate ranging from approximately zero degrees to approximately 90 degrees.

Further, in one example embodiment of the invention, the multi-gate field effect transistor apparatus, such as described herein, can be a FinFET. Although example embodiments of the invention depicted in the figures are built on a silicon on insulator (SOI) substrate (such as, for example, component 120 in FIG. 1), at least one embodiment of the invention is not limited to such, and can also be built on a bulk substrate.

Another aspect of the invention includes designing a multi-gate field effect transistor (for example, a FinFET) via arranging a source terminal, a drain terminal and a gate terminal with a tapered-gate profile to create a wider gate width on a bottom of a fin. As detailed herein, the gate is wrapped around the fin in the FinFET structure. Such techniques can additionally include incorporating a hardmask into the field effect transistor, wherein the gate terminal wraps around the hardmask. As noted herein, the hardmask can have a thickness of varying range.

Also, at least one embodiment of the invention can include arranging a doping profile flush with the tapered-gate profile, arranging a doping profile overlapping the tapered-gate profile, arranging the tapered-gate profile overlapping a doping profile, etc. A doping profile can include, by way of example, a BOX doping profile.

Additionally, as detailed herein, in accordance with an aspect of the invention, the gate terminal is arranged so that the tapered-gate profile includes an angle of the tapered-gate ranging from approximately zero degrees to approximately 90 degrees.

By way of example, an embodiment of the invention can be implemented in any integrated circuit (IC)/chip using FinFET as a device component, as would be appreciated by one skilled in the art.

Although illustrative embodiments of the present invention have been described herein with reference to the accompanying drawings, it is to be understood that the invention is not limited to those precise embodiments, and that various other changes and modifications may be made by one skilled in the art without departing from the scope or spirit of the invention.

1. A method for designing a nonplanar multi-gate fin field effect transistor (FinFET), comprising:
arranging a source terminal, a drain terminal and a gate terminal with a tapered-gate profile along each FinFET sidewall gate to create a wider gate width on a bottom of a fin.

2. The method of claim 1, wherein the apparatus is implemented on a silicon on insulator (SOI) substrate or a bulk substrate.

3. The method of claim 1, further comprising incorporating a hardmask into the multi-gate field effect transistor.

4. The method of claim 3, wherein the gate terminal wraps around the hardmask.

5. The method of claim 3, wherein hardmask has a thickness ranging from approximately 0.5 nanometers to approximately 3 nanometers.

6. The method of claim 3, wherein hardmask has a thickness ranging from approximately 20 nanometers to approximately 30 nanometers.

7. The method of claim 1, further comprising arranging a doping profile flush with the tapered-gate profile.

8. The method of claim 1, further comprising arranging a doping profile overlapping the tapered-gate profile.

9. The method of claim 1, further comprising arranging the tapered-gate profile overlapping a doping profile.

10. The method of claim 1, wherein arranging a source terminal, a drain terminal and a gate terminal with a tapered-gate profile to create a wider gate width on a bottom of a fin provides longer gate length in a bottom portion of a fin to lessen short channel effect penalty.

11. The method of claim 1, wherein the tapered-gate profile includes an angle of the tapered-gate ranging from approximately zero degrees to approximately 90 degrees.
